(19) United States
(12) Patent Application Publication
(10) Pub. No.: US 2024/0297119 A1
(43) Pub. Date: Sep. 5, 2024

(54) LIQUID METAL CONNECTION DEVICE AND METHOD

(71) Applicant: Intel Corporation, Santa Clara, CA (US)

(72) Inventors: Srikant Nekkanty, Chandler, AZ (US); Karumbu Meyyappan, Portland, OR (US); Andres Ramirez Macias, Zapopan (MX); Zhe Chen, Shanghai (CN); Jeffory L. Smalley, East Olympia, WA (US); Zhichao Zhang, Chandler, AZ (US); Steven A. Klein, Chandler, AZ (US); Eric Erike, Mesa, AZ (US)

(21) Appl. No.: 18/573,116

(22) PCT Filed: Dec. 22, 2021
(86) PCT No.: PCT/CN2021/140395

§ 371 Date: Dec. 21, 2023

(51) Int. Cl. H01L 23/532; H01L 23/32; H01L 23/40; H01L 23/498; H01L 23/528

(52) U.S. Cl. CPC H01L 23/53209; H01L 23/32; H01L 23/4093; H01L 23/49811; H01L 23/5283

(57) ABSTRACT

An electronic device (100, 800, 1000) and associated methods are disclosed. In one example, the electronic device (100, 800, 1000) includes an interconnect socket (102, 302, 402, 802, 1004, 1320, 1402, 1506) that includes a liquid metal. In selected examples, the interconnect socket (102, 302, 402) includes a resilient material spacer (130, 230, 330, 430) located between pins (110, 210, 310, 410) in an array of pins (110, 210, 310, 410). In selected examples, the electronic device (1000) includes configurations to aid in de-socketing.

### TECHNICAL FIELD

Embodiments described herein generally relate to electronic devices and methods. Example devices include sockets and semiconductor die packages.

### BACKGROUND

Current land grid array (LGA) socket technology poses pin count scalability limitations with an increasing amount of mechanical load and complex loading mechanism solutions. It is desired to provide electronic devices, socket solutions, tools and methods that address these concerns, and other technical challenges.

### BRIEF DESCRIPTION OF THE DRAWINGS

FIG. 1 shows an electronic device in accordance with some example embodiments.

FIG. 2A-2C show a portion of a socket connection in accordance with some example embodiments.

FIG. 3 shows a portion of another socket connection in accordance with some example embodiments.

FIG. 4 shows a portion of another socket connection in accordance with some example embodiments.

FIG. 5A-5C show socket pin examples in accordance with some example embodiments.

FIG. 6 shows a manufacture step of forming a pin in accordance with some example embodiments.

FIG. 7 shows a manufacture step of forming another pin in accordance with some example embodiments.

FIG. 8 shows another electronic device in accordance with some example embodiments.

FIG. 9A shows a portion of another socket connection in accordance with some example embodiments.

FIG. 9B shows an electronic device incorporating the socket connection of FIG. 9A in accordance with some example embodiments.

FIG. 10 shows another electronic device in accordance with some example embodiments.

FIG. 11 shows an exploded view of an electronic device in accordance with some example embodiments.

FIG. 12A shows a top view of a portion of an electronic device in accordance with some example embodiments.

FIG. 12B shows a bottom view of a portion of an electronic device in accordance with some example embodiments.

FIG. 13 shows a semiconductor die package extraction tool in accordance with some example embodiments.

FIG. 14A-14B show another semiconductor die package extraction tool in accordance with some example embodiments.

FIG. 15 shows another semiconductor die package extraction tool in accordance with some example embodiments.

FIG. 16 shows a system that may incorporate electronic devices, sockets, tools, and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

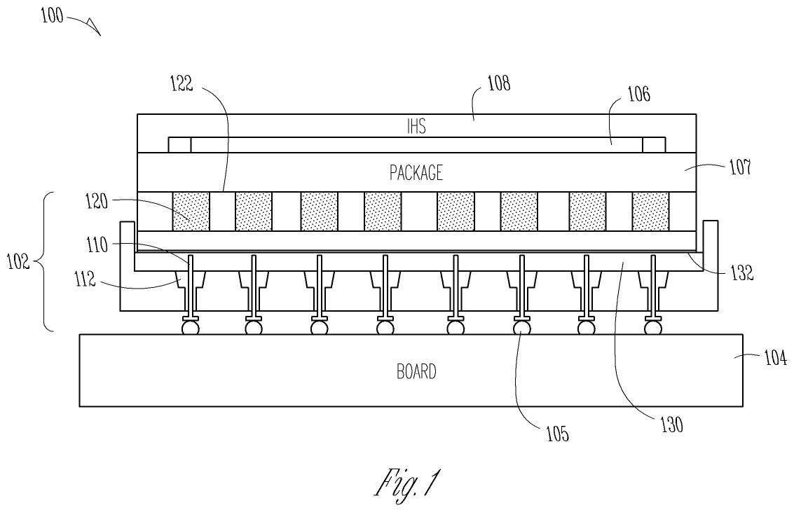

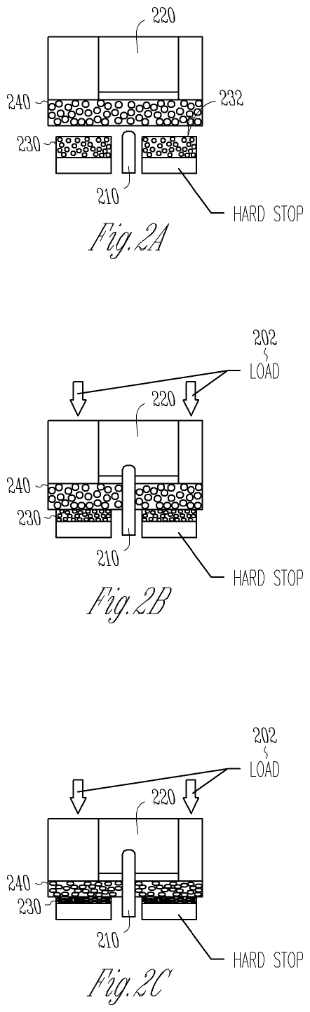

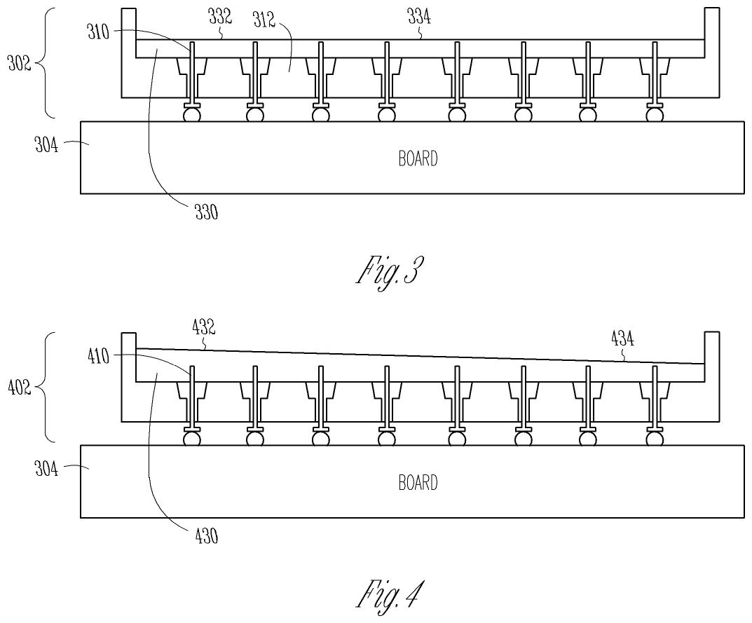

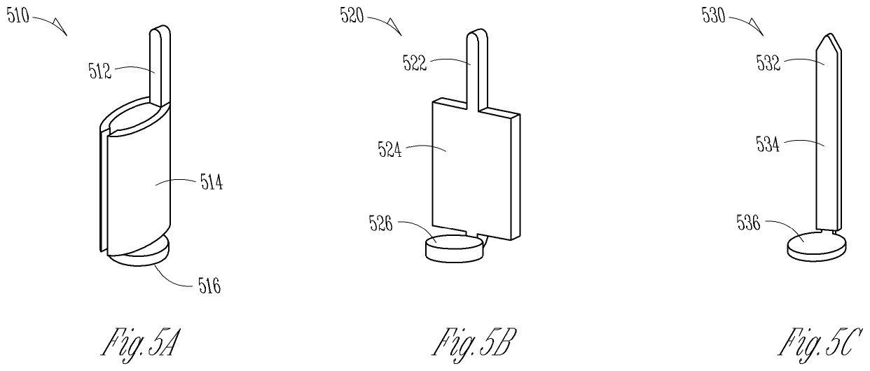

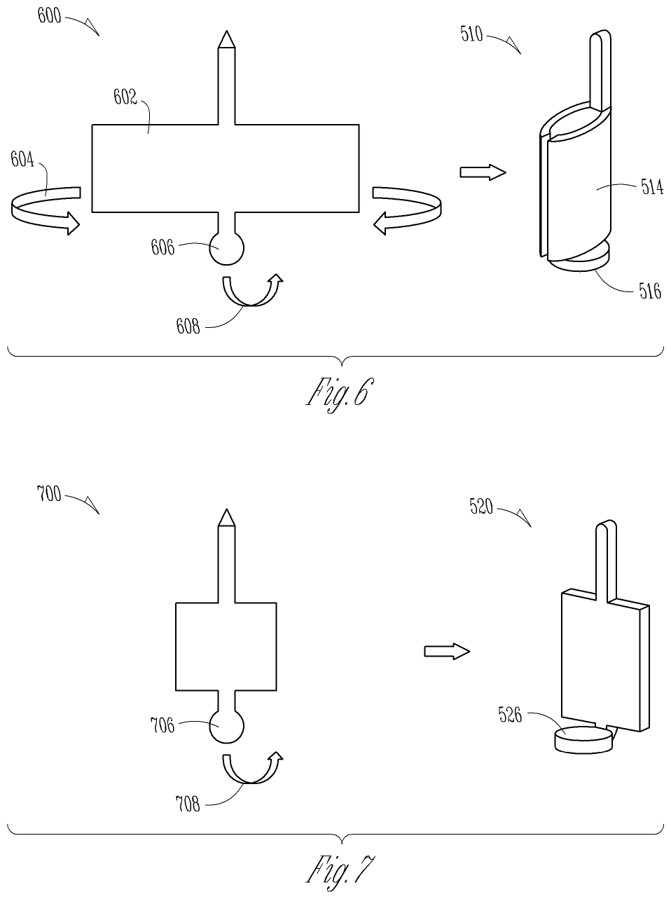

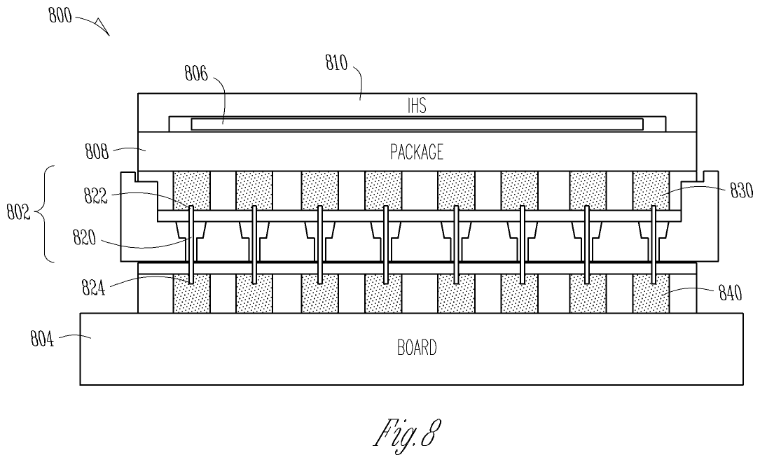

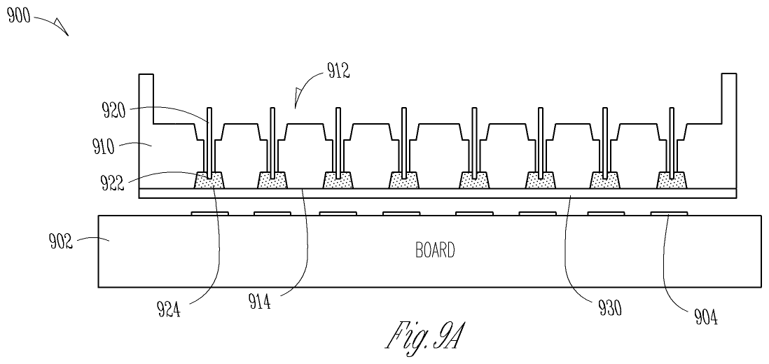

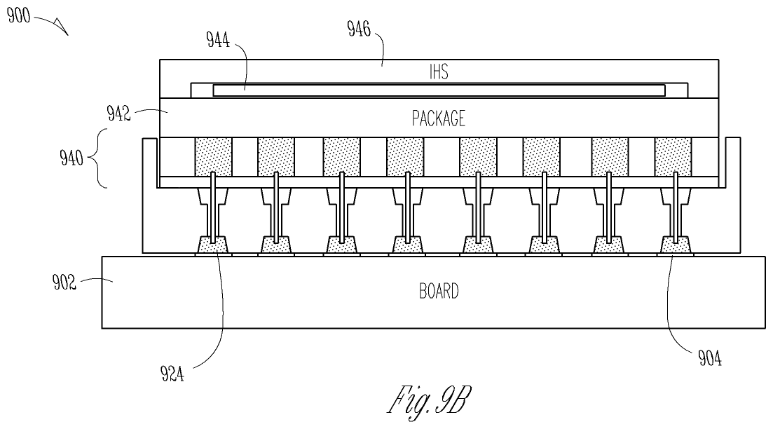

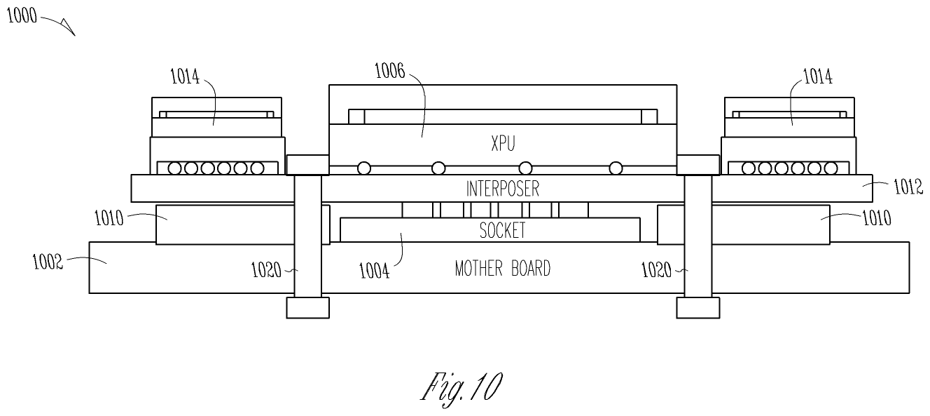

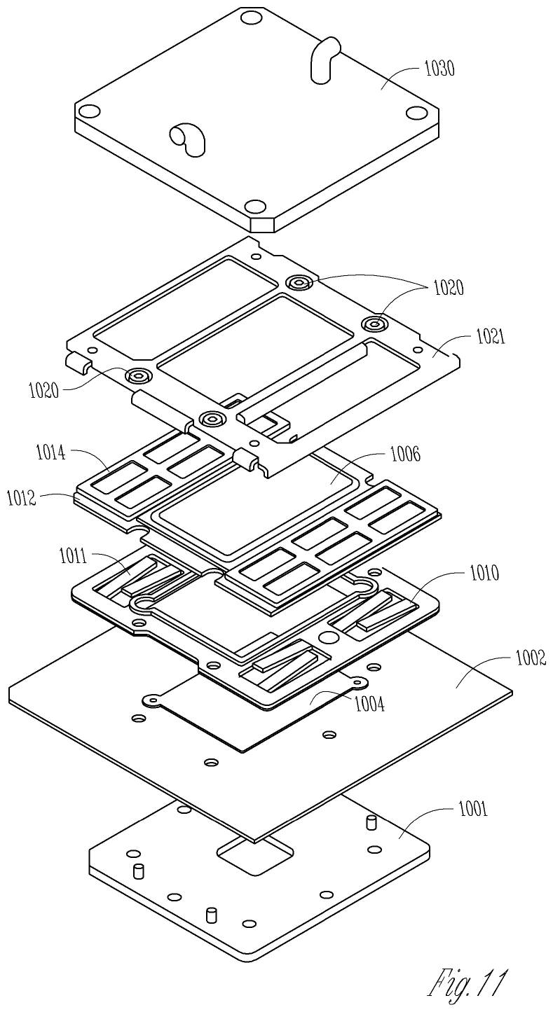

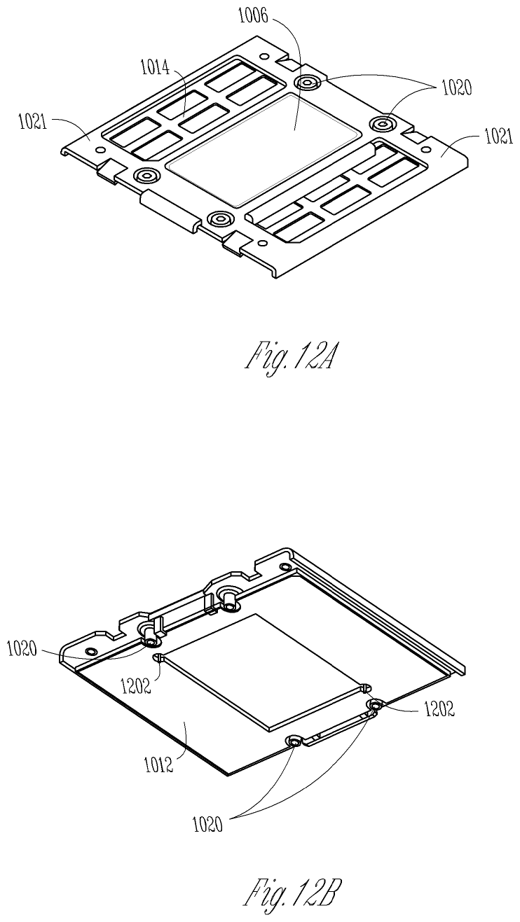

FIG. 1 shows an electronic device 100, including an electronic interconnect socket 102. The socket 102 couples between a circuit board 104 and a semiconductor die 106 that is mounted on a package substrate 107. In one example, an integrated heat spreader 108 is further coupled over the semiconductor die 106. In the example shown, the socket 102 includes an array of pins 110 on a first surface 112. The socket 102 further includes an array of liquid metal filled reservoirs 120 on a second surface 122. In the example of FIG. 1, the pins 110 are connected to the circuit board 104 with solder 105, although the invention is not so limited. Using solder 105 to connect a bottom half of socket 102 is possible without heating any components in the top half (die 106, package 107, etc.) by merely separating the socket into its two halves and only soldering the bottom half.

Although in the example of FIG. 1, the pins 110 are on a bottom surface, and the liquid metal filled reservoirs 120 are on a top surface, the invention is not so limited. One of ordinary skill in the art, having the benefit of the present disclosure, will recognize that the top and bottom structures can also be reversed. Similarly, a male and female arrangement of the socket is shown, however, which portion is male, and which portion is female is relative, and such configurations can be reversed without departing from the scope of the invention.

In one example, the liquid metal filled reservoirs 120 include gallium or a gallium alloy. Gallium and gallium alloys can be tailored by varying alloying elements and element amounts to be liquid at room temperature. Metals that are liquid at room temperature are useful because they easily form an electrical connection when a solid metal mating component penetrates the liquid metal. Example solid metal components include, but are not limited to, pins, rods, plates, or other geometries. Notably, this type of liquid metal electrical connection is easily made, and easily disconnected with minimal force.

The liquid metal of the liquid metal filled reservoirs 120 can also be any metal that has a melting point at or near room temperature. Some examples include cesium, gallium, and rubidium. In some examples, the liquid metal is an alloy of gallium and indium. The liquid metal may also be a eutectic that is an alloy having a melting point at or near room temperature.

In the example of FIG. 1, the pins 110 in the array of pins have a pin height. A resilient material spacer 130 is shown located between pins 110 in the array of pins. A surface 132 of the resilient material spacer 130 is shown in FIG. 1, at or above ends of the pins 110 in an uncompressed state. FIGS. 2A-2C below illustrate how the surface 132 of the resilient material spacer 130 exposes the ends of the pins 110 in a compressed state.

In one example, the resilient material spacer 130 includes a porous polymer. An inclusion of pores may make the resilient material spacer 130 more compressible due to the inclusion of air spaces. Examples of resilient materials include, but are not limited to, polymers, elastomers in general, specific elastomers such as polyimides, silicones, polyurethanes, etc.

FIGS. 2A-2C show an individual pin connection similar to the pins 110 in socket 102 from FIG. 1. In FIG. 2A a pin 210 is shown with resilient material spacer 230 located between pins 210. A surface 232 of the resilient material spacer 230 is shown in FIG. 2A, at or above an end of the pin 210 in an uncompressed state. An advantage of having the surface 232 at or above an end of the pin includes protection of a potentially fragile pin 210, and reduced likelihood of injury to a user from a sharp pin 210.

In the example of FIG. 2A, the resilient material spacer 230 includes gaps where the pin 210 is, however, the surface 232 is at or above the end of the pin. In other examples, the resilient material spacer 230 is continuous and encases tips of the pins 210.

In FIG. 2B, pressure is applied, as indicated by arrows 202. The resilient material spacer 230 is compressed, and the end of the pin 210 protrudes past the surface 232. In FIG. 2B, the end of the pin 210 further penetrates a resilient cap 240 over a liquid metal filled reservoir 220. Although a cap 240 is useful to retain liquid metal in the liquid metal filled reservoir 220 the cap may not be included in all examples. In selected example, surface tension holds the liquid metal within the liquid metal filled reservoir 220 without the need for a cap 240. Advantages of a cap include more secure containment of liquid metal, and a moisture barrier function.

In FIG. 2C, the end of the pin 210 is within the liquid metal filled reservoir 220 and an electrical connection has been made. In one example, as shown in FIG. 2C, both the resilient material spacer 230 and the resilient cap 240 are compressed to allow penetration of the pin 210 within the liquid metal filled reservoir 220. In one example, the resilient material spacer 230 includes a porous polymer. In one example, the resilient cap 240 includes a porous polymer. An inclusion of pores may make the resilient material spacer 230 and/or the resilient cap 240 more compressible due to the inclusion of air spaces.

FIG. 3 shows a socket portion 302. The socket portion 302 is shown coupled to a circuit board 304. An array of pins 310 are shown embedded within a socket body 312. A resilient material spacer 330 is shown with a surface 332 at or above an end of the pins 310 in an uncompressed state. In the example of FIG. 3, the resilient material spacer 330 is continuous and encases tips of the pins 310. In FIG. 3, a skin 334 is included, covering the resilient material spacer 330 at the surface 332. In one example, the skin 334 is also resilient. In one example, the skin 334 provides added safety and moisture sealing properties to protect the pins 310.

FIG. 4 shows another example socket portion 402. The socket portion 402 is shown coupled to a circuit board 404. An array of pins 410 are shown embedded within a socket body 412. A resilient material spacer 430 is shown with a first end surface 432 and a second end surface 434 in an uncompressed state. As shown, the first end surface 432 and the second end surface 434 define a varying thickness to provide a gradient of pin exposure. In operation, when compressed from above by a matin socket portion, the second end surface 434 will be exposed first due to the thickness that is shorter that at the first end surface 432. By exposing a fraction of the pins 410 at a time, an insertion force is controlled, and spread over time as pins are gradually exposed from right to left in the Figure.

FIG. 4 shows a gradually tapering gradient of varying thickness in the resilient material spacer 430, although the invention is not so limited. Other examples of varying thickness include, but are not limited to a stepped thickness with one or more discrete thicknesses between the first end surface 432 and the second end surface 434.

FIGS. 5A-5C show a number of options for different pin configuration for use in sockets as described in the present disclosure. In one example more than one different pin configuration is used in a single socket. Different pin geometries can be tailored to their function in the socket.

FIG. 5A shows a pin 510 having a generally cylindrical central portion 514. The pin 510 further includes a sharp tip 512 for penetrating a liquid metal reservoir as described in examples of the present disclosure. A solder pad 516 is shown on a bottom connection region. In one example, the solder pad 516 is used to connect to other circuitry, such as a printed circuit board. In one example, the generally cylindrical central portion 514 is optimally suited for differential input/output signaling operation.

FIG. 5B shows a pin 520 having a generally flat central portion 524. The pin 520 further includes a sharp tip 522 for penetrating a liquid metal reservoir as described in examples of the present disclosure. A solder pad 526 is shown on a bottom connection region. In one example, the solder pad 526 is used to connect to other circuitry, such as a printed circuit board. In one example, the generally flat central portion 524 is optimally suited for single ended memory operations, such as dual data rate (DDR) random access memory signaling (RAM) operation.

FIG. 5C shows a pin 530 having a thin, generally flat central portion 534. The pin 530 further includes a sharp tip 532 for penetrating a liquid metal reservoir as described in examples of the present disclosure. A solder pad 536 is shown on a bottom connection region. In one example, the solder pad 536 is used to connect to other circuitry, such as a printed circuit board. In one example, the thinner, generally flat central portion 534 is optimally suited for low frequency signaling and/or power delivery operations.

By combining more than one different pin geometries, for example the pin geometries described in FIGS. 5A-5C or others, the individual functions of each pin can be optimized, and operation of the socket as a whole will be improved.

In one example, one or more of the pins are formed into their final geometries from flat metal. For example, FIG. 6 shows a method of formation for pin 510 of FIG. 5A from a flat starting piece 600. The flat starting piece 600 can be formed by laser cutting, etching, stamping, or other suitable formation techniques. FIG. 6 shows curling of flat section 602 as indicated by arrows 604 to form the generally cylindrical section 514. Additionally, FIG. 6 shows folding of flat section 606 as indicated by arrow 608 to form the solder pad 516. Forming from a flat starting piece 600 provides an inexpensive manufacturing technique to form various pin geometries for optimized socket operation as described above.

FIG. 7 shows a method of formation for pin 520 of FIG. 5B from a flat starting piece 700. As described in FIG. 6, the flat starting piece 700 can be formed by laser cutting, etching, stamping, or other suitable formation techniques. FIG. 7 shows folding of flat section 706 as indicated by arrow 708 to form the solder pad 526.

FIG. 8 shows an electronic device 800, including an electronic interconnect socket 802. The socket 802 couples between a circuit board 804 and a semiconductor die 806 that is mounted on a package substrate 808. In one example, an integrated heat spreader 810 is further coupled over the semiconductor die 806. In the example shown, the socket 802 includes an array of pins 820. The socket 802 further includes a first array of liquid metal filled reservoirs 830 above the pins 810, and a second array of liquid metal filled reservoirs 840 below the pins 810. In the example shown, the pins 810 include a top end 822 and a bottom end 824, and the socket 802 is two sided, as described below. In one example, both ends 822, 824 are sharp to penetrate the liquid metal filled reservoirs 830, 840. In selected examples, a sharpened end is not required, as interfacing with liquid metal does not require a sharp end for penetration. In a socketing operation, pressure is applied from above, and the top end 822 of pins 810 penetrate the first array of liquid metal filled reservoirs 830, while simultaneously the bottom end 824 of pins 810 penetrate the second array of liquid metal filled reservoirs 840.

FIGS. 9A and 9B show another example of an electronic device incorporating a socket. FIG. 9A shows an array of pins 920 embedded within a socket body 910, the array of pins 920 exposed on a first major surface 912 of the socket body 910. An array of liquid metal filled reservoirs 924 is further shown on a second major surface 914 of the socket body 910. The array of pins each include a bottom end 922. The pins 920 pass through the socket body 910 and are coupled to the array of liquid metal filled reservoirs 924 at the bottom end 922. An adhesive film 930 is further shown over the array of liquid metal filled reservoirs 924 on the second surface 914. In operation, the adhesive film 930 is used to couple the second surface 914 to a circuit board 902. In FIG. 9A, the circuit board 902 is shown with a number of connection pads 904. The adhesive film 930 adheres the socket body 910 to the circuit board 902 and the array of liquid metal filled reservoirs 924 make an electrical connection with the connection pads 904. In one example, a peel off layer (not shown) exposes the adhesive film 930 before connection to the circuit board 902.

FIG. 9B shows the socket body 910 assembled to the circuit board 902 with a semiconductor die 944 and package substrate 942 coupled to the socket body 910. In the example shown, an integrated heat spreader 946 is further coupled above the semiconductor die 944.

FIG. 10 shows another configuration of an electronic device 1000 that incorporates a socket as described in the present disclosure. FIG. 10 shows a liquid metal socket 1004 coupled to a circuit board 1002. A semiconductor die package 1006 is shown above the liquid metal socket 1004, and coupled to the circuit board 1002 through the liquid metal socket 1004. One or more biasing devices 1010 are shown between the circuit board 1002 and the semiconductor die package 1006. In operation, if the semiconductor die package 1006 is to be removed from the socket 1004, it may be difficult to extract the semiconductor die package 1006 due to friction from a large number of pins in the socket 1004. The inclusion of the one or more biasing devices 1010 provides an extraction force that helps in removal of the semiconductor die package 1006 or an intervening structure that couples the semiconductor die package 1006 to the socket 1004. When socketing the semiconductor die package 1006 or an intervening structure, the biasing force must be overcome. In the example, shown, one or more fasteners 1020 are included for coupling the semiconductor die package 1006 to the circuit board 1002. When the one or more fasteners 1020 are secured, the one or more biasing devices store a releasing force. When the one or more fasteners 1020 are released, the releasing force of the one or more biasing devices 1010 drives the semiconductor die package 1006 out of engagement with the liquid metal socket 1004.

In the example of FIG. 10, an interposer 1012 is shown as an intervening structure between the semiconductor die package 1006 and the socket 1004. In the example shown, one or more additional devices 1014 are included on the interposer 1012. In one example, the one or more additional devices 1014 include semiconductor memory, such as random access memory (RAM).

FIG. 11 shows an exploded view of other structures that may be included in the electronic device 1000. A bottom mount plate 1001 is shown below the circuit board 1002. The liquid metal socket 1004 is shown on the circuit board 1002. In one example, the liquid metal socket 1004 is a pin array half of a socket surface mounted to a printed circuit board, although the invention is not so limited. In one example, a liquid metal filled reservoir array is on the interposer 1012, configured to mate with a pin array half of a socket, although the invention is not so limited. The one or more biasing devices 1010 are shown as included within a biasing plate. In the example of FIG. 11, a biasing plate includes one or more leaf springs 1011 included within the plate. One of ordinary skill in the art, having the benefit of the present disclosure, will recognize that other biasing devices apart from a plate, leaf springs, etc. are possible within the scope of the invention. Other examples may include, but are not limited to, elastomer inserts, coil springs, etc.

FIG. 11 further shows the interposer 1012, with the semiconductor die package 1006 and one or more additional devices 1014 coupled to the interposer 1012. In the example of FIG. 11, a top plate 1021 is shown that includes the one or more fasteners 1020. In operation, the one or more fasteners 1020 pass through holes or notches in the interposer 1012 and the circuit board 1002 and couple to corresponding fastener components in the bottom mount plate 1001. Examples of fasteners include, but are not limited to, threaded screws and corresponding threaded nuts. Other fasteners are also within the scope of the invention.

FIG. 11 also shows a removable cooling solution 1030. In one example, the cooling solution 1030 is a heat spreader that is configured to move heat from high concentration areas to lower concentration areas. In one example, the cooling solution 1030 is configured for heat removal. Examples of heat removal include, but are not limited to, evaporative cooling, thermoelectric devices, circulated liquid cooling systems, etc.

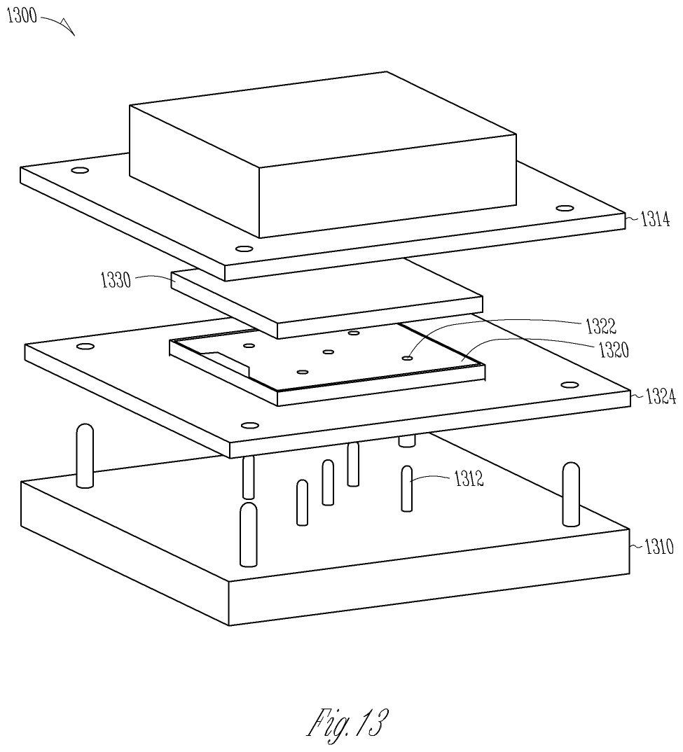

FIG. 12A shows a detailed view of a top surface of the top plate 1021. FIG. 12B shows a detailed view of a bottom surface of the top plate 1021 and the interposer 1012. In one example the one or more fasteners 1020 provide a coarse level of location for alignment with the liquid metal socket 1004. FIG. 12B further shows one or more fine alignment pins 1202 to aid in location with respect to the liquid metal socket 1004.

FIGS. 10 and 11 illustrated the inclusion of one or more biasing devices 1010 top aid in de-socketing or removal of the semiconductor die package 1006 or intervening structures from the liquid metal socket 1004. In selected examples, one or more tools may be used for removal. In one example, the one or more tools are used instead of the one or more biasing devices 1010. In one example the one or more tools are used in addition to the one or more biasing devices 1010.

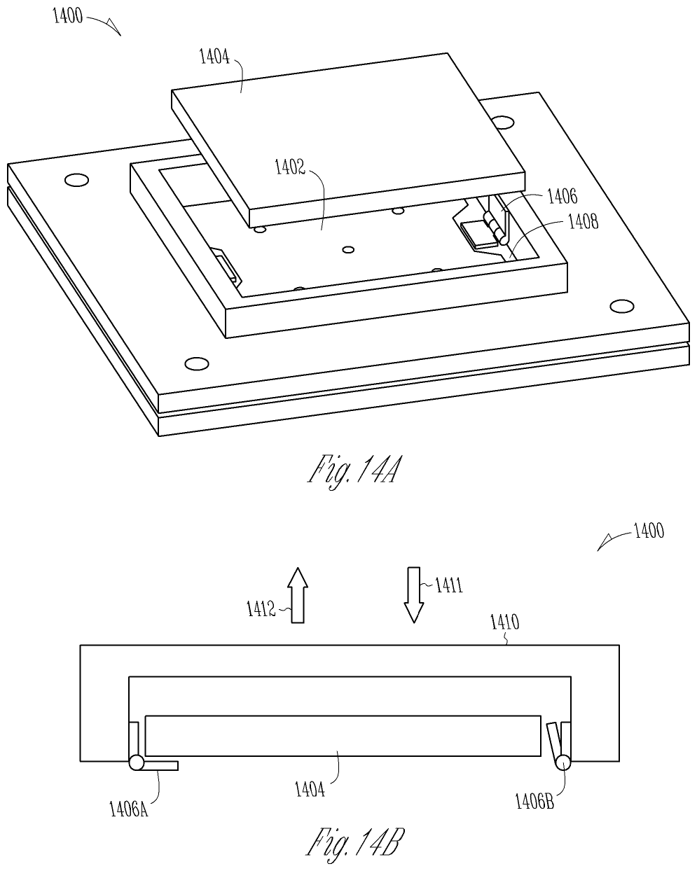

FIG. 13 shows a semiconductor die package extraction tool 1300. The tool of FIG. 13 includes one or more extraction push pins 1312 that are configured to mate with one or more access holes 1322 through a liquid metal socket 1320. In operation, the one or more extraction push pins 1312 contact the semiconductor die package 1330 from a backside of the semiconductor die package and push the semiconductor die package 1330 out of engagement with the liquid metal socket 1320. FIG. 13 further shows a base 1310 that holds the one or more extraction push pins 1312 at their necessary locations and alignment. A pusher 1314 is further shown that may be included to aid in consistent pressure on all sides of an interposer 1324 and to aid in alignment of the one or more extraction push pins 1312 during extraction.

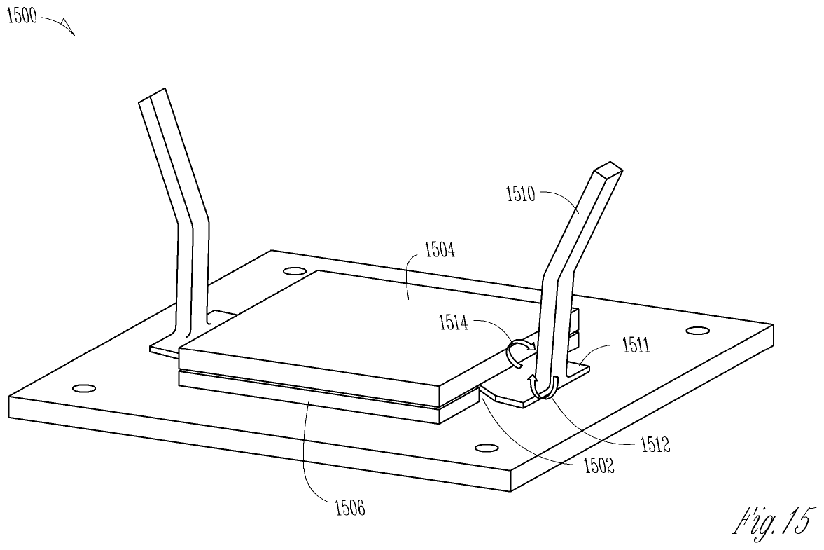

FIGS. 14A-14B show another example of a semiconductor die package extraction tool 1400. The tool includes one or more unidirectional linkages 1406 configured to hook within a recess 1408 in a liquid metal socket 1402 under a portion of the semiconductor die package 1404 when applied from a first direction and hold the semiconductor die package during extraction. FIG. 14B shows a side view of the tool 1400 in operation. A first unidirectional linkage 1406A is shown in an extraction ready condition. A second unidirectional linkage 1406B is shown in an intermediate tool placement condition.

When a tool body 1410 is pushed down (as indicated by arrow 1411) over the semiconductor die package 1404, the second unidirectional linkage 1406B is shown deflecting over the die package 1404 to place the tool body 1410 over the die package 1404. After passing a bottom of the die package 1404, the unidirectional linkage will snap into an extraction condition as shown in the first unidirectional linkage 1406A. Recesses 1408 from FIG. 14A provides space for the unidirectional linkages 1406A, 1406B.

Because the linkages are unidirectional, they will latch over the semiconductor die package 1404 and hold it within the tool body 1410. When the tool body 1410 is pulled up (as indicated by arrow 1412) the captive semiconductor die package 1404 will be removed from the socket 1402. Although hinges are shown as the unidirectional linkages, the invention is not so limited. Other linkages that operate unidirectionally are also within the scope of the invention.

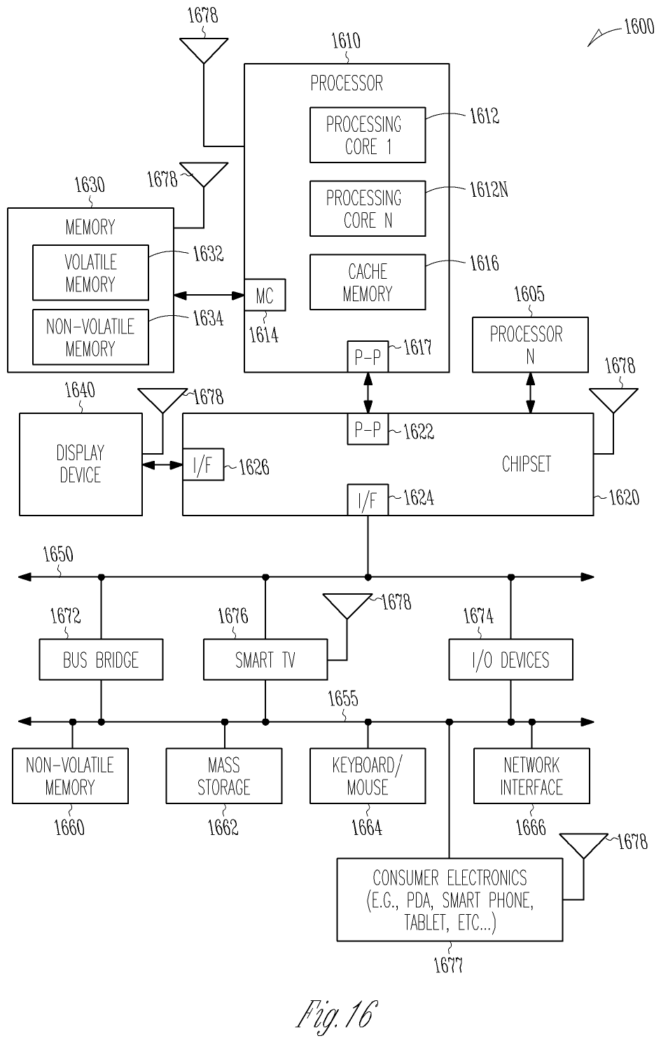

FIG. 15 shows another example of a semiconductor die package extraction tool 1500. The tool in operation includes one or more pry regions 1502 between the semiconductor die package 1504 and the liquid metal socket 1506. A tool 1510 is shown with a paddle 1511 inserted in the one or more pry regions 1502 for an extraction operation. The paddle 1511 is configured such that more than one axis of actuation is available. For example, if the tool 1510 is twisted about arrow 1512, the paddle will provide a prying action. Additionally, if the tool 1510 is twisted about arrow 1514, the paddle will provide a different prying action. In one example, two or more tools 1510 may be used to provide equal prying force on opposite sides of the semiconductor die package 1504 for more consistent extraction.

FIG. 16 illustrates a system level diagram, depicting an example of an electronic device (e.g., system) that may include sockets, electronic devices, tools, and/or methods described above. In one embodiment, system 1600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1600 includes a system on a chip (SOC) system.

In one embodiment, processor 1610 has one or more processor cores 1612 and 1612N, where 1612N represents the Nth processor core inside processor 1610 where N is a positive integer. In one embodiment, system 1600 includes multiple processors including 1610 and 1605, where processor 1605 has logic similar or identical to the logic of processor 1610. In some embodiments, processing core 1612 includes, but is not limited to, pre-fetch logic to fetch instructions, decode logic to decode the instructions, execution logic to execute instructions and the like. In some embodiments, processor 1610 has a cache memory 1616 to cache instructions and/or data for system 1600. Cache memory 1616 may be organized into a hierarchal structure including one or more levels of cache memory.

In some embodiments, processor 1610 includes a memory controller 1614, which is operable to perform functions that enable the processor 1610 to access and communicate with memory 1630 that includes a volatile memory 1632 and/or a non-volatile memory 1634. In some embodiments, processor 1610 is coupled with memory 6130 and chipset 1620. Processor 1610 may also be coupled to a wireless antenna 1678 to communicate with any device configured to transmit and/or receive wireless signals. In one embodiment, an interface for wireless antenna 1678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1634 includes, but is not limited to, flash memory, phase change memory (PCM), read-only memory (ROM), electrically erasable programmable read-only memory (EEPROM), or any other type of non-volatile memory device.

Memory 1630 stores information and instructions to be executed by processor 1610. In one embodiment, memory 1630 may also store temporary variables or other intermediate information while processor 1610 is executing instructions. In the illustrated embodiment, chipset 1620 connects with processor 1610 via Point-to-Point (PtP or P-P) interfaces 1617 and 1622. Chipset 1620 enables processor 1610 to connect to other elements in system 1600. In some embodiments of the example system, interfaces 1617 and 1622 operate in accordance with a PtP communication protocol such as the Intel® QuickPath Interconnect (QPI) or the like. In other embodiments, a different interconnect may be used.

In some embodiments, chipset 1620 is operable to communicate with processor 1610, 1605N, display device 1640, and other devices, including a bus bridge 1672, a smart TV 1676, I/O devices 1674, nonvolatile memory 1660, a storage medium (such as one or more mass storage devices) 1662, a keyboard/mouse 1664, a network interface 1666, and various forms of consumer electronics 1677 (such as a PDA, smart phone, tablet etc.), etc. In one embodiment, chipset 1620 couples with these devices through an interface 1624. Chipset 1620 may also be coupled to a wireless antenna 1678 to communicate with any device configured to transmit and/or receive wireless signals. In one example, any combination of components in a chipset may be separated by a continuous flexible shield as described in the present disclosure.

Chipset 1620 connects to display device 1640 via interface 1626. Display 1640 may be, for example, a liquid crystal display (LCD), a light emitting diode (LED) array, an organic light emitting diode (OLED) array, or any other form of visual display device. In some embodiments of the example system, processor 1610 and chipset 1620 are merged into a single SOC. In addition, chipset 1620 connects to one or more buses 1650 and 1655 that interconnect various system elements, such as I/O devices 1674, nonvolatile memory 1660, storage medium 1662, a keyboard/mouse 1664, and network interface 1666. Buses 1650 and 1655 may be interconnected together via a bus bridge 1672.

In one embodiment, mass storage device 1662 includes, but is not limited to, a solid state drive, a hard disk drive, a universal serial bus flash memory drive, or any other form of computer data storage medium. In one embodiment, network interface 1666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 16 are depicted as separate blocks within the system 1600, the functions performed by some of these blocks may be integrated within a single semiconductor circuit or may be implemented using two or more separate integrated circuits. For example, although cache memory 1616 is depicted as a separate block within processor 1610, cache memory 1616 (or selected aspects of 1616) can be incorporated into processor core 1612.

To better illustrate the method and apparatuses disclosed herein, a non-limiting list of embodiments is provided here:

Example 1 includes an electronic interconnect socket. The electronic interconnect socket includes an array of pins on a first surface, an array of liquid metal filled reservoirs on a second surface, and a resilient material spacer located between pins in the array of pins, wherein a surface of the resilient material spacer is at or above ends of the pins in an uncompressed state, and exposes the ends of the pins in a compressed state.

Example 2 includes the electronic interconnect socket of example 1, wherein the resilient material includes a porous polymer.

Example 3 includes the electronic interconnect socket of any one of examples 1-2, wherein the resilient material is continuous and encases tips of the array of pins.

Example 4 includes the electronic interconnect socket of any one of examples 1-3, further including a skin covering the resilient material spacer.

Example 5 includes the electronic interconnect socket of any one of examples 1-4, wherein the resilient material spacer includes a varying thickness to provide a gradient of pin exposure.

Example 6 includes the electronic interconnect socket of any one of examples 1-5, wherein the resilient material spacer is stepped.

Example 7 includes the electronic interconnect socket of any one of examples 1-6, further including a resilient cap over the array of liquid metal filled reservoirs.

Example 8 includes the electronic interconnect socket of any one of examples 1-7, wherein pins in the array of pins include different cross section geometries.

Example 9 includes the electronic interconnect socket of any one of examples 1-8, wherein at least some of the pins in the array of pins include formed flat metal pins.

Example 10 includes the electronic interconnect socket of any one of examples 1-9, wherein at least some of the pins in the array of pins include a solder pad substantially normal to a pin axis.

Example 11 includes the electronic interconnect socket of any one of examples 1-10, wherein at least some of the pins in the array of pins are sharp on both ends and wherein a pin half of the socket is two sided.

Example 12 includes an electronic device. The electronic device includes an array of pins embedded within a socket body, the array of pins exposed on a first major surface of the socket body, an array of liquid metal filled reservoirs on a second major surface of the socket body, the array of pins passing through the socket body and coupled to the array of liquid metal filled reservoirs, and an adhesive film over the array of liquid metal filled reservoirs on the second surface.

Example 13 includes the electronic device of example 12, further including a peel off covering over the adhesive film and the array of liquid metal filled reservoirs on the second surface.

Example 14 includes the electronic device of any one of examples 12-13, further including a mating socket body, the mating socket body configured to engage the first major surface of the socket body, the mating socket body including a second array of liquid metal filled reservoirs.

Example 15 includes the electronic device of any one of examples 12-14, wherein the mating socket body is coupled to a land side of a package substrate.

Example 16 includes the electronic device of any one of examples 12-15, further including a semiconductor die coupled to a die side of the package substrate.

Example 17 includes the electronic device of any one of examples 12-16, further including an integrated heat spreader over and in thermal communication with the semiconductor die.

Example 18 includes an electronic device. The electronic device includes a liquid metal socket coupled to a circuit board, a semiconductor die package, one or more biasing devices between the circuit board and the semiconductor die package, and one or more fasteners coupling the semiconductor die package to the circuit board, wherein the one or more biasing devices store a releasing force to drive the semiconductor die package out of engagement with the liquid metal socket upon release of the one or more fasteners.

Example 19 includes the electronic device of example 18, wherein the one or more biasing devices are included in a biasing plate.

Example 20 includes the electronic device of any one of examples 18-19, wherein the one or more biasing devices include leaf springs.

Example 21 includes the electronic device of any one of examples 18-20, wherein the semiconductor die package is coupled to an interposer, further including one or more memory devices coupled to the interposer adjacent to the semiconductor die package, and wherein the one or more biasing devices are between the interposer and the circuit board.

Example 22 includes the electronic device of any one of examples 18-21, further including fine alignment pins to aid in location with respect to the liquid metal socket.

Example 23 includes the electronic device of any one of examples 18-22, further including a detachable heat transfer device.

Example 24 includes the electronic device of any one of examples 18-23, further including a semiconductor die package extraction tool, the tool including one or more extraction push pins configured to mate with one or more access holes through the liquid metal socket and to contact the semiconductor die package from a backside of the semiconductor die package.

Example 25 includes the electronic device of any one of examples 18-24, further including a semiconductor die package extraction tool, the tool including one or more unidirectional linkages configured to hook under a portion of the semiconductor die package when applied from a first direction and hold the semiconductor die package during extraction.

Example 26 includes the electronic device of any one of examples 18-25, further including one or more pry regions between the semiconductor die package and the liquid metal socket, and a semiconductor die package extraction tool, the tool including more than one axis of actuation.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/of” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1.-26. (canceled)

27. An electronic interconnect socket, comprising:
an array of pins on a first surface;
an array of liquid metal filled reservoirs on a second surface; and
a resilient material spacer located between pins in the array of pins, wherein a surface of the resilient material spacer is at or above ends of the pins in an uncompressed state, and exposes the ends of the pins in a compressed state.

28. The electronic interconnect socket of claim 27, wherein the resilient material includes a porous polymer.

29. The electronic interconnect socket of claim 27, wherein the resilient material is continuous and encases tips of the array of pins.

30. The electronic interconnect socket of claim 27, further including a skin covering the resilient material spacer.

31. The electronic interconnect socket of claim 27, wherein the resilient material spacer includes a varying thickness to provide a gradient of pin exposure.

32. The electronic interconnect socket of claim 27, wherein the resilient material spacer is stepped.

33. The electronic interconnect socket of claim 27, further including a resilient cap over the array of liquid metal filled reservoirs.

34. The electronic interconnect socket of claim 27, wherein pins in the array of pins include different cross section geometries.

35. The electronic interconnect socket of claim 27, wherein at least some of the pins in the array of pins include formed flat metal pins.

36. The electronic interconnect socket of claim 35, wherein at least some of the pins in the array of pins include a solder pad substantially normal to a pin axis.

37. The electronic interconnect socket of claim 27, wherein at least some of the pins in the array of pins are sharp on both ends and wherein a pin half of the socket is two sided.

38. An electronic device, comprising:
an array of pins embedded within a socket body, the array of pins exposed on a first major surface of the socket body;
an array of liquid metal filled reservoirs on a second major surface of the socket body, the array of pins passing through the socket body and coupled to the array of liquid metal filled reservoirs; and
an adhesive film over the array of liquid metal filled reservoirs on the second surface.

39. The electronic device of claim 38, further including a peel off covering over the adhesive film and the array of liquid metal filled reservoirs on the second surface.

40. The electronic device of claim 39, further including a mating socket body, the mating socket body configured to engage the first major surface of the socket body, the mating socket body including a second array of liquid metal filled reservoirs.

41. The electronic device of claim 40, wherein the mating socket body is coupled to a land side of a package substrate.

42. The electronic device of claim 41, further including a semiconductor die coupled to a die side of the package substrate.

43. The electronic device of claim 42, further including an integrated heat spreader over and in thermal communication with the semiconductor die.

44. An electronic device, comprising:
a liquid metal socket coupled to a circuit board;
a semiconductor die package;
one or more biasing devices between the circuit board and the semiconductor die package; and
one or more fasteners coupling the semiconductor die package to the circuit board, wherein the one or more biasing devices store a releasing force to drive the semiconductor die package out of engagement with the liquid metal socket upon release of the one or more fasteners.

45. The electronic device of claim 44, wherein the semiconductor die package is coupled to an interposer;
further including one or more memory devices coupled to the interposer adjacent to the semiconductor die package; and
wherein the one or more biasing devices are between the interposer and the circuit board.

46. The electronic device of claim 44, further including a detachable heat transfer device.
